(19) United States
(12) Patent Application Publication
(10) Pub. No.: US 2024/0258352 A1
(43) Pub. Date: Aug. 1, 2024

(54) IMAGE SENSOR

(71) Applicant: SAMSUNG ELECTRONICS CO., LTD., Suwon-si (KR)

(72) Inventors: Dongchan KIM, Suwon-si (KR); Byoungho KWON, Suwon-si (KR); Beomsuk LEE, Suwon-si (KR)

(21) Appl. No.: 18/410,259

(22) Filed: Jan. 11, 2024

(30) Foreign Application Priority Data
Jan. 30, 2023 (KR) 10-2023-0011868

(51) Int. Cl. H01L 27/146

(52) U.S. Cl. CPC H01L 27/14629; H01L 27/14621; H01L 27/14627; H01L 27/14636

(57) ABSTRACT

An image sensor including a substrate including an active pixel region and a peripheral region surrounding the active pixel region; a metal layer on a peripheral region of the substrate; a lower reflective layer on the substrate and the metal layer; a resonance layer on the lower reflective layer; and an upper reflective layer on the resonance layer, wherein the resonance layer has a first thickness on the active pixel region in a vertical direction perpendicular to an upper surface of the substrate and a second thickness in the vertical direction on the peripheral region, and the first thickness is greater than the second thickness.

### CROSS-REFERENCE TO RELATED APPLICATION

This application is based on and claims priority under 35 U.S.C. § 119 to Korean Patent Application No. 10-2023-0011868, filed on Jan. 30, 2023, in the Korean Intellectual Property Office, the disclosure of which is incorporated by reference herein in its entirety.

### BACKGROUND

### 1 Field

Embodiments relate to an image sensor.

### 2. Description of the Related Art

Image sensors may be used to convert an optical image into an electrical signal. Image sensors may include charge coupled device (CCD) image sensors and complementary metal oxide semiconductor (CMOS) image sensors (CISs). Such an image sensor may include a plurality of pixels arranged in a two-dimensional matrix, and each of the pixels may be configured to output an image signal from light energy. Each of the pixels may be configured to accumulate a photocharge corresponding to the amount of light incident through a photoelectric conversion element, and output a pixel signal based on the accumulated photocharge.

### SUMMARY

The embodiments may be realized by providing an image sensor including a substrate including an active pixel region and a peripheral region surrounding the active pixel region; a metal layer on the peripheral region of the substrate; a lower reflective layer on the substrate and the metal layer; a resonance layer on the lower reflective layer; and an upper reflective layer on the resonance layer, wherein the resonance layer has a first thickness on the active pixel region in a vertical direction perpendicular to an upper surface of the substrate and a second thickness in the vertical direction on the peripheral region, and the first thickness is greater than the second thickness.

The embodiments may be realized by providing an image sensor including a substrate including an active pixel region and a peripheral region surrounding the active pixel region, the active pixel region including an active region and a dummy region; a wiring structure on a lower surface of the substrate; a metal layer on the peripheral region of the substrate; a lower reflective layer on the substrate and the metal layer; a resonance layer on the lower reflective layer; and an upper reflective layer on the resonance layer, wherein the resonance layer includes a first material layer covering the lower reflective layer on the active pixel region and on the peripheral region, first patterns extending through the first material layer on the active pixel region in a vertical direction perpendicular to an upper surface of the substrate, and a first residual layer on the first material layer and the first patterns on the dummy region.

The embodiments may be realized by providing an image sensor including a substrate including an active pixel region and a peripheral region surrounding the active pixel region; a metal layer on the peripheral region of the substrate; a lower reflective layer on the substrate and the metal layer; a resonance layer including a first resonance layer and a second resonance layer that are sequentially on the lower reflective layer; an upper reflective layer on the resonance layer; a plurality of color filters including a first color filter on the upper reflective layer on the active pixel region and a second color filter on the upper reflective layer on the peripheral region; and a micro-lens on the first color filter, wherein the first resonance layer has a first thickness in a vertical direction perpendicular to an upper surface of the substrate on the active pixel region and a second thickness in the vertical direction on the peripheral region, the first thickness is greater than the second thickness, and a thickness in the vertical direction of the second resonance layer on the active pixel region is the same as a thickness in the vertical direction of the second resonance layer on the peripheral region.

### BRIEF DESCRIPTION OF THE DRAWINGS

Features will be apparent to those of skill in the art by describing in detail exemplary embodiments with reference to the attached drawings in which:

FIG. 1 is a block diagram illustrating an image sensor according to an embodiment;

FIG. 2 is a plan view illustrating an image sensor according to an embodiment;

FIG. 3 is a cross-sectional view illustrating an image sensor according to an embodiment;

FIG. 4 is an enlarged cross-sectional view of a portion EX1 of FIG. 3;

FIG. 5 is a cross-sectional view illustrating an image sensor according to an embodiment;

FIG. 6 is an enlarged cross-sectional view of a portion EX2 of FIG. 5;

FIGS. 7A to 7H are cross-sectional views of stages in a method of manufacturing an image sensor, according to embodiments; and

FIGS. 8A to 8F are cross-sectional views of stages in a method of manufacturing an image sensor, according to embodiments.

### DETAILED DESCRIPTION

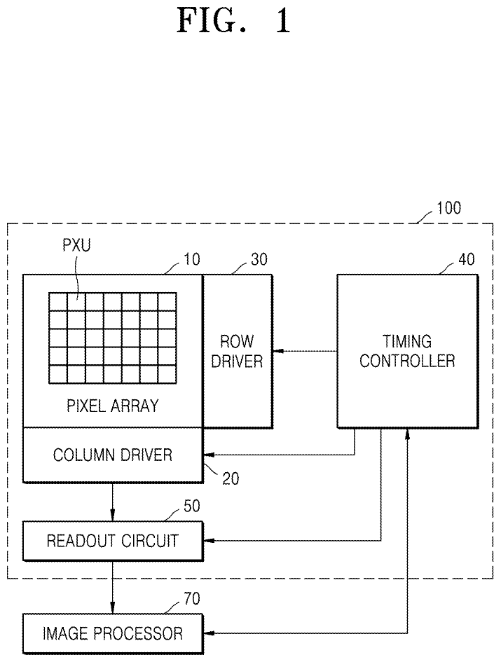

FIG. 1 is a block diagram illustrating an image sensor 100 according to an embodiment.

Referring to FIG. 1, the image sensor 100 of the embodiment may include a pixel array 10 and circuits for controlling the pixel array 10. In an implementation, circuits for controlling the pixel array 10 may include a column driver 20, a row driver 30, a timing controller 40, and a readout circuit 50.

The image sensor 100 may operate according to control commands received from an image processor 70. The image sensor 100 may convert light received from an external object into an electrical signal and may output the electrical signal to the image processor 70. In an implementation, the image sensor 100 may be a complementary metal oxide semiconductor (CMOS) image sensor.

The pixel array 10 may include a plurality of unit pixels PXU having a two-dimensional array structure and arranged in a matrix form in a plurality of row lines and a plurality of column lines.

Each of the unit pixels PXU may include a photoelectric conversion element. The photoelectric conversion element may generate charge by receiving light from an object. The image sensor 100 may perform an autofocus function using the phase difference between pixel signals generated by the photoelectric conversion elements included in the unit pixels PXU. Each of the unit pixels PXU may include a pixel circuit configured to generate a pixel signal from a charge generated by the photoelectric conversion element.

The column driver 20 may include a correlated double sampler (CDS), an analog-to-digital converter (ADC), or the like. The CDS may be connected through the column lines to unit pixels PXU that are included in a row selected by a row selection signal supplied from the row driver 30 and may perform correlated double sampling to detect a reset voltage and a pixel voltage. The ADC may convert the reset voltage and the pixel voltage detected by the CDS into digital signals and may transmit the digital signals to the readout circuit 50.

The readout circuit 50 may include a latch or buffer circuit capable of temporarily storing digital signals, an amplification circuit, or the like, and may generate image data by temporarily storing or amplifying digital signals received from the column driver 20. Operation timings of the column driver 20, the row driver 30, and the readout circuit 50 may be determined by the timing controller 40, and the timing controller 40 may operate according to control commands transmitted from the image processor 70.

The image processor 70 may perform signal processing on image data output from the readout circuit 50 and may output the processed image data to a display device or store the processed image data in a storage device such as a memory. The image sensor 100 may be mounted on an autonomous vehicle, and the image processor 70 may process image data and transmit the image data to a main controller that controls the autonomous vehicle.

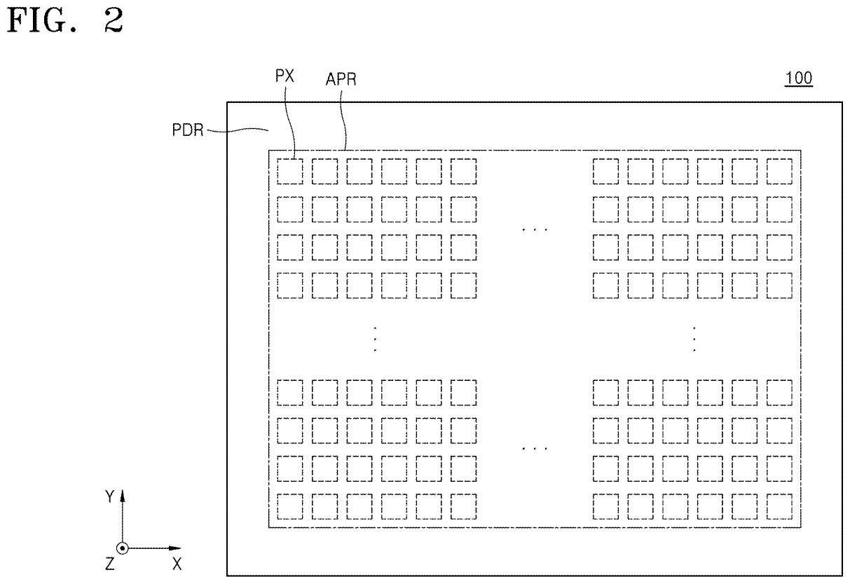

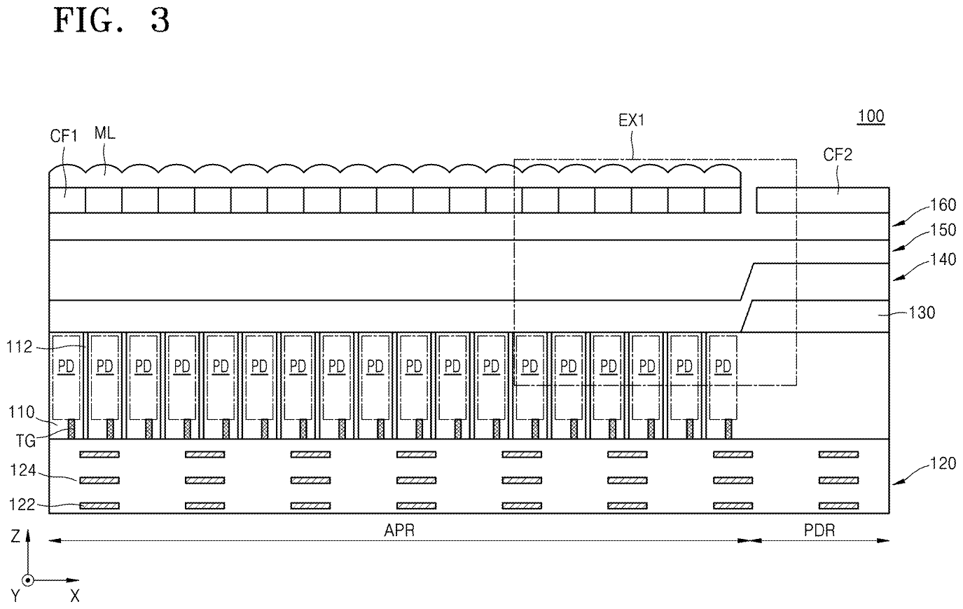

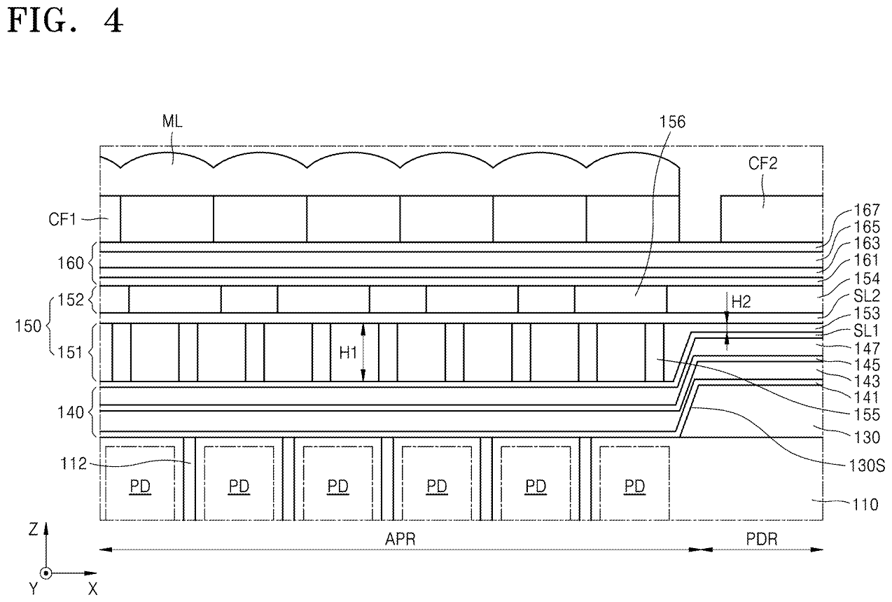

FIG. 2 is a plan view illustrating an image sensor 100 according to an embodiment. FIG. 3 is a cross-sectional view illustrating the image sensor 100 according to an embodiment. FIG. 4 is an enlarged cross-sectional view illustrating a portion EX1 of FIG. 3.

Referring to FIGS. 2 to 4, the image sensor 100 may include a substrate 110, a wiring structure 120, a metal layer 130, a lower reflective layer 140, a resonance layer 150, an upper reflective layer 160, first and second color filters CF1 and CF2, and a micro-lens ML.

The substrate 110 may include an active pixel region APR and a peripheral region PDR. The active pixel region APR may be a center region of the substrate 110 in a plan view. The active pixel region APR may include a plurality of pixels PX. A plurality of photoelectric conversion regions PD may be in the pixels PX, respectively. On the active pixel region APR, the pixels PX may be arranged in rows and columns to form a matrix form in a first horizontal direction (X direction) parallel to an upper surface of the substrate 110 and a second horizontal direction (Y direction) perpendicular to the first horizontal direction and parallel to the upper surface of the substrate 110.

The peripheral region PDR may be an edge region of the substrate 110 in a plan view. The peripheral region PDR may surround the active pixel region APR. In an implementation, the peripheral region PDR may be a region including pad terminals thereon. Electrical signals generated by the pixels PX may be output through the pad terminals, or electrical signals or voltages input from the outside may be transmitted to the pixels PX through the pad terminals. In an implementation, the peripheral region PDR may be a region including optical black pixels thereon. The optical black pixels may function as reference pixels for the active pixel region APR and may perform a function of automatically correcting a dark signal. In an implementation, the peripheral region PDR may include a first region including optical black pixels thereon and a second region including pad terminals thereon. The first region may surround the active pixel region APR, and the second region may surround the first region.

The substrate 110 may have upper and lower surfaces facing each other. Hereinafter, the upper surface thereof may be referred to as a rear surface and the lower surface thereof may be referred to as a front surface. The substrate 110 may be a semiconductor substrate. In an implementation, the semiconductor substrate may include germanium (Ge), silicon-germanium (SiGe), silicon-carbide (SiC), gallium-arsenic (GaAs), indium-arsenic (InAs), or indium-phosphorus (InP). In an implementation, the substrate 110 may include conductive regions, e.g., wells doped with a dopant or structures doped with a dopant. The dopant may include, e.g., a p-type dopant such as aluminum (Al), boron (B), indium (In), or gallium (Ga). As used herein, the term “or” is not an exclusive term, e.g., “A or B” would include A, B, or A and B.

The photoelectric conversion regions PD may be in the substrate 110. In an implementation, the photoelectric conversion regions PD may be in the active pixel region APR of the substrate 110. The photoelectric conversion regions PD may generate photocharges by absorbing light incident from the outside and may accumulate the photocharges, thereby converting optical signals into electrical signals. The photoelectric conversion regions PD may include photodiodes and wells inside the substrate 110. The photoelectric conversion regions PD may be regions doped with a dopant having a conductivity type that is opposite the conductivity type of the substrate 110. The dopant may include, e.g., an n-type dopant such as phosphorus (P), arsenic (As), bismuth (Bi), or antimony (Sb). In an implementation, as illustrated in FIGS. 3 and 4, the photoelectric conversion regions PD may only be in the active pixel region APR of the substrate 110. In an implementation, the peripheral region PDR may be a region including optical black pixels thereon, and the photoelectric conversion regions PD may also be in the peripheral region PDR of the substrate 110.

Transfer gates TG may be inside the substrate 110. In an implementation, the transfer gates TG may be in the active pixel region APR of the substrate 110. The transfer gates TG may extend from the lower surface of the substrate 110 into the substrate 110. In an implementation, a device isolation layer defining active regions and floating diffusion (FD) regions may be further included on the lower surface of the substrate 110. The transfer gates TG may transfer charges generated and accumulated in the photoelectric conversion regions PD to the FD regions, and the FD regions may store the charges received through the transfer gates TG.

A pixel isolation structure 112 may extend through the substrate 110 in a vertical direction (Z direction) perpendicular to the upper surface of the substrate 110. The pixel isolation structure 112 may be between the pixels PX to physically and electrically separate each of the pixels PX from adjacent pixels PX. In an implementation, the pixel isolation structure 112 may include an insulating material such as a silicon oxide, silicon nitride, or silicon oxynitride.

The wiring structure 120 may be on the lower surface (e.g., the front surface) of the substrate 110. In an implementation, the wiring structure 120 may have a stacked structure in which a plurality of layers are stacked. The wiring structure 120 may perform signal processing on electrical signals generated by the photoelectric conversion regions PD. The wiring structure 120 may include a plurality of wiring layers 122 and an insulating layer 124. The insulating layer 124 may be on the lower surface of the substrate 110 and may electrically insulate the wiring layers 122 from each other. In an implementation, the insulating layer 124 may include an insulating material such as a silicon oxide, silicon nitride, or silicon oxynitride. Each of the wiring layers 122 may be electrically connected to a transistor on the lower surface of the substrate 110. In an implementation, each of the wiring layers 122 may include, e.g., undoped polysilicon, polysilicon doped with a dopant, a metal, a metal silicide, a metal nitride, or a metal-containing layer. In an implementation, the wiring layers 122 may include tungsten (W), aluminum (Al), copper (Cu), tungsten silicide, titanium silicide, tungsten nitride, titanium nitride, doped polysilicon, or the like. In an implementation, a support substrate may be on a lower surface of the wiring structure 120. The support substrate may have logic circuits for driving pixel circuits and may support the substrate 110.

The metal layer 130 may be on the upper surface of the substrate 110. The metal layer 130 may have a sidewall 130S that is inclined downwardly from the peripheral region PDR toward the active pixel region APR. A portion of the metal layer 130 overlapping or having the inclined sidewall 130S in the vertical direction (Z direction) may be on the active pixel region APR, and the rest of the metal layer 130 may be on the peripheral region PDR. On the peripheral region PDR, the metal layer 130 may block incident light such that the incident light may not reach the substrate 110, may connect the substrate 110 and the support substrate to each other, or may function as pad terminals (described above) to output electrical signals generated by the pixels PX or transmit electrical signals or voltages input from the outside to the pixels PX. In an implementation, the peripheral region PDR may be a region including pad terminals, and the metal layer 130 may function as the pad terminals. In an implementation, the peripheral region PDR may be a region including optical black pixels, and the metal layer 130 may block light incident from the outside toward the substrate 110. In an implementation, the metal layer 130 may include a metal such as tungsten, copper, titanium, or aluminum.

The lower reflective layer 140 may be on the substrate 110. The lower reflective layer 140 may cover the upper surface of the substrate 110 on the active pixel region APR and may cover the metal layer 130 on the peripheral region PDR. In an implementation, a portion of the lower reflective layer 140 overlapping the inclined sidewall 130S of the metal layer 130 in the vertical direction (Z direction) may also be inclined along the inclined sidewall 130S, and the rest of the lower reflective layer 140 (other than the overlapping portion) may be flat in the first horizontal direction (X direction) parallel to the upper surface of the substrate 110. The lower reflective layer 140 may include a first lower reflective layer 141, a second lower reflective layer 143, a third lower reflective layer 145, and a fourth lower reflective layer 147 that are sequentially stacked on the substrate 110. In an implementation, each of the first to fourth lower reflective layers 141, 143, 145, and 147 may include an insulating material such as a silicon oxide or a titanium oxide. In an implementation, the first lower reflective layer 141 and the third lower reflective layer 145 may include the same material. In an implementation, the first lower reflective layer 141 and the third lower reflective layer 145 may include a titanium oxide. In an implementation, the second lower reflective layer 143 and the fourth lower reflective layer 147 may include the same material. In an implementation, the second lower reflective layer 143 and the fourth lower reflective layer 147 may include a silicon oxide. In an implementation, the first lower reflective layer 141 and the third lower reflective layer 145 may include the same material, the second lower reflective layer 143 and the fourth lower reflective layer 147 may include the same material, and the material included in the first lower reflective layer 141 and the third lower reflective layer 145 may be different from the material included in the second lower reflective layer 143 and the fourth lower reflective layer 147. In an implementation, the first lower reflective layer 141 and the third lower reflective layer 145 may include a titanium oxide, and the second lower reflective layer 143 and the fourth lower reflective layer 147 may include a silicon oxide. In an implementation, as illustrated in FIGS. 3 and 4, the lower reflective layer 140 may have a stacked structure in which four layers are stacked in the vertical direction (Z direction), or a different number of layers may be included.

A first etch stop layer SL1 may be on the lower reflective layer 140. A portion of the first etch stop layer SL1 overlapping the inclined sidewall 130S of the metal layer 130 in the vertical direction (Z direction) may have the same slope as the slope of the inclined sidewall 130S, and the rest of the first etch stop layer SL1 other than the overlapping portion may be flat in the first horizontal direction (X direction). In an implementation, a vertical level (e.g., distance from the substrate 110 in the vertical Z direction) of the first etch stop layer SL1 on the peripheral region PDR may be higher than the vertical level thereof on the active pixel region APR. The first etch stop layer SL1 may include, e.g., a silicon oxide, a titanium oxide, or a hafnium oxide.

The resonance layer 150 may be on the first etch stop layer SL1. The resonance layer 150 may cause light having a specific wavelength to resonate. The resonance layer 150 may include a first resonance layer 151 on the first etch stop layer SL1 and a second resonance layer 152 on the first resonance layer 151.

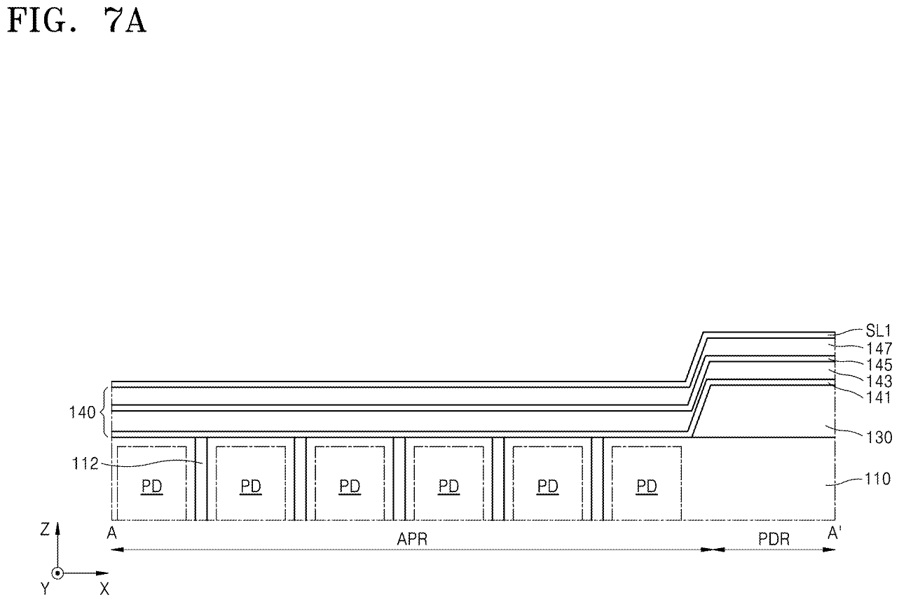

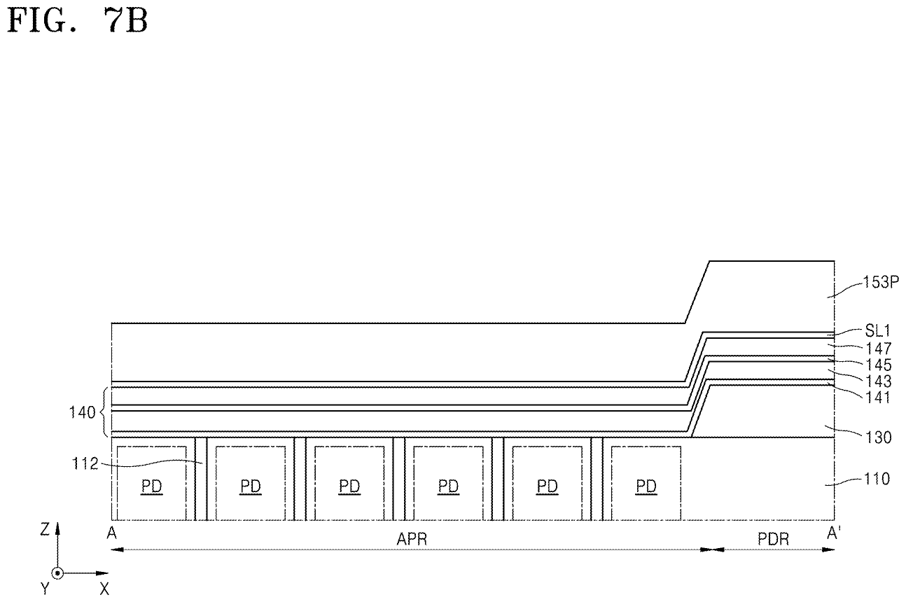

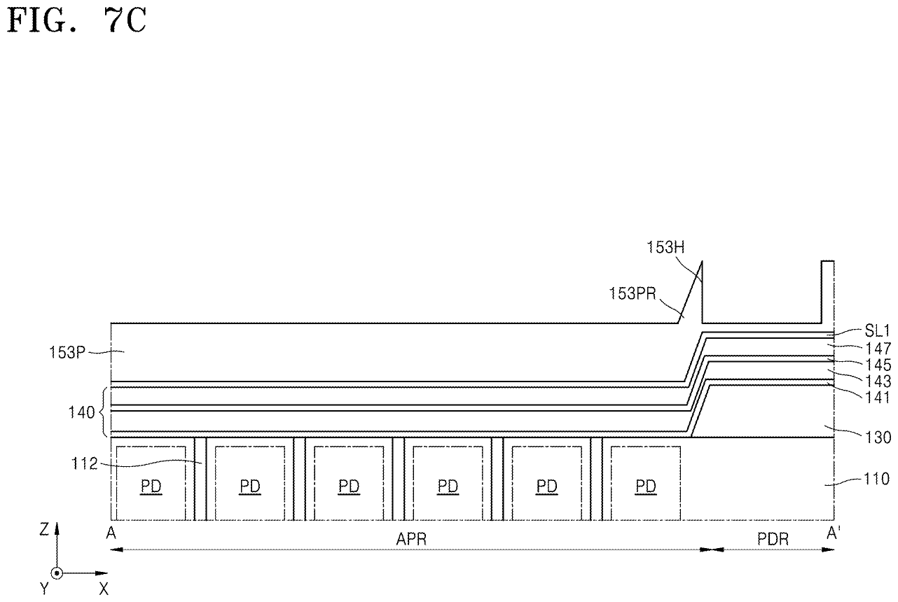

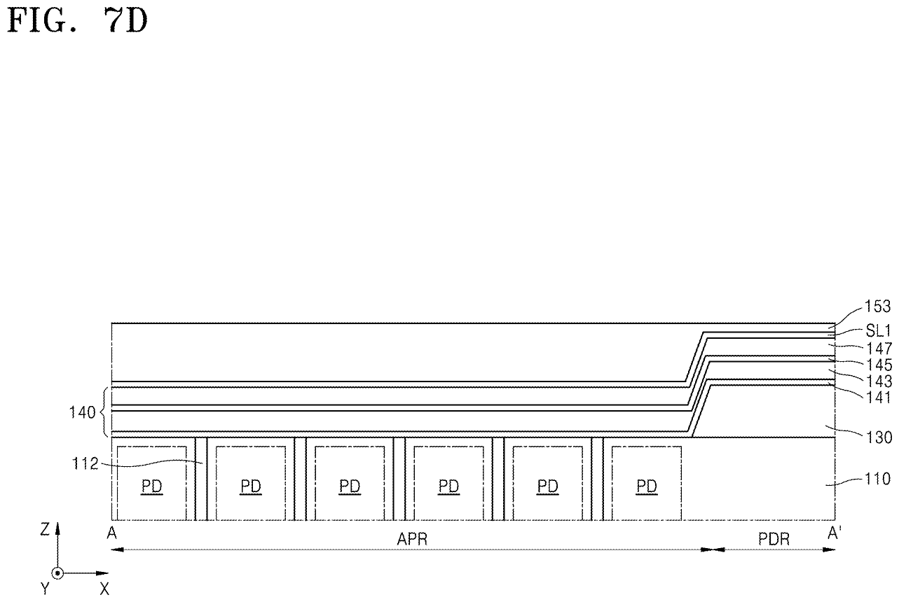

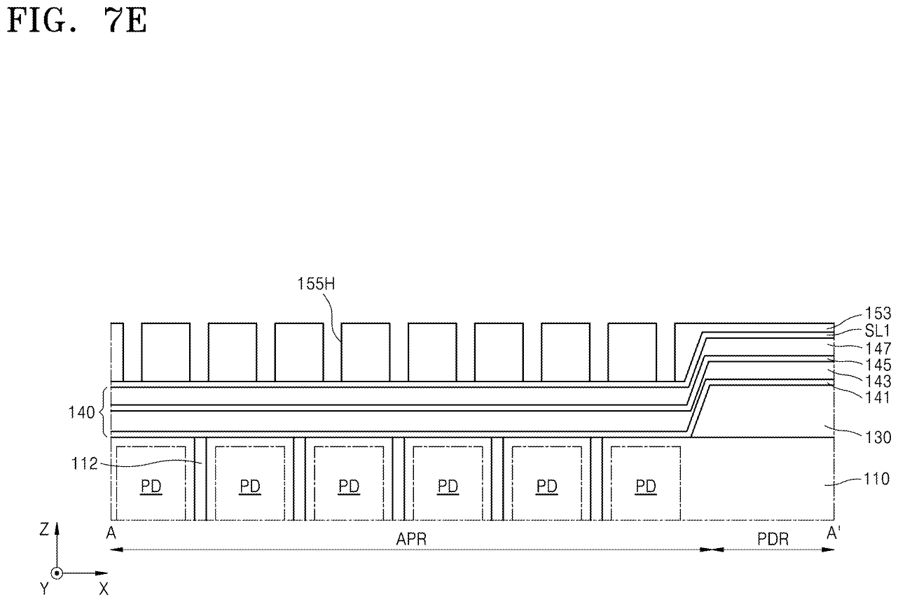

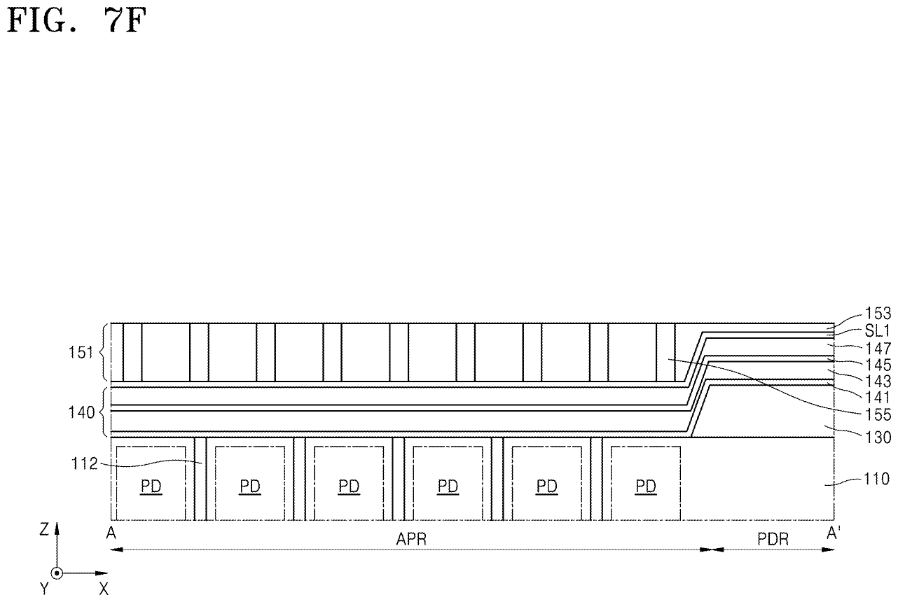

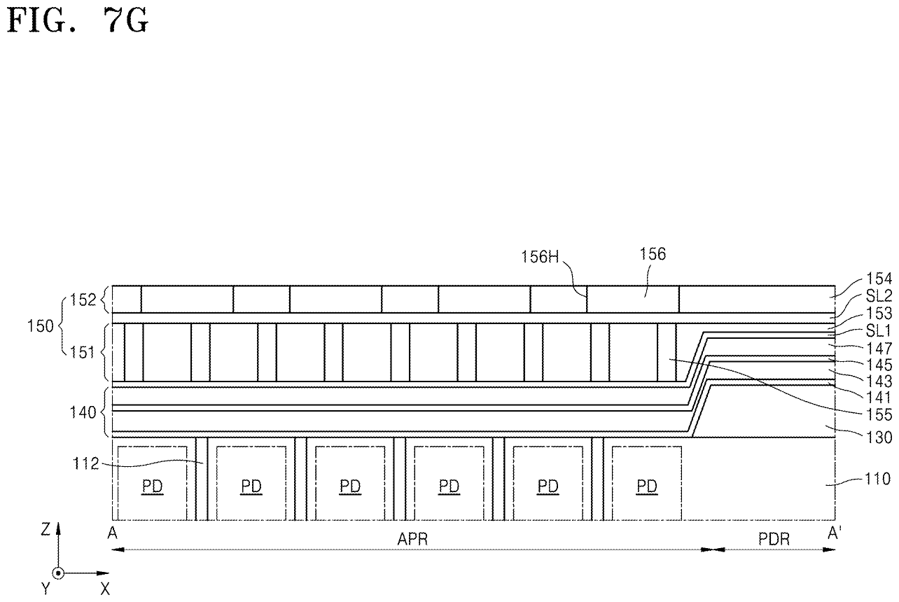

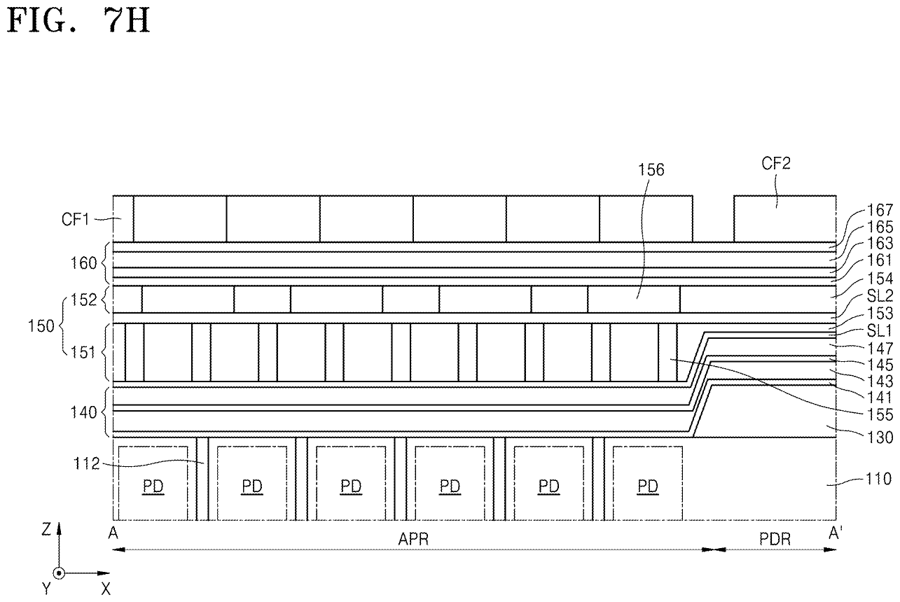

A lower section of a portion of the first resonance layer 151 overlapping the inclined sidewall 130S of the metal layer 130 in the vertical direction (Z direction) may have the same slope as the slope of the inclined sidewall 130S, and the rest of the first resonance layer 151 other than the overlapping portion may be flat in the first horizontal direction (X direction). In an implementation, on the active pixel region APR, the first resonance layer 151 may have a first thickness H1 in the vertical direction (Z direction), and on the peripheral region PDR, the first resonance layer 151 may have a second thickness H2 in the vertical direction (Z direction). The first thickness H1 may be greater than the second thickness H2. The difference between the first thickness H1 and the second thickness H2 may be due to an etching process and a planarization process that are performed on a material layer 153P (refer to FIG. 7C) in a method of manufacturing the image sensor 100 as described later with reference to FIGS. 7A to 7H. In an implementation, a vertical level of an upper surface of the first resonance layer 151 on the active pixel region APR may be the same as a vertical level thereof on the peripheral region PDR. In an implementation, a vertical level of a lower surface of the first resonance layer 151 on the peripheral region PDR may be higher than the vertical level thereof on the active pixel region APR.

The first resonance layer 151 may include a first material layer 153 and a plurality of first patterns 155. The first material layer 153 may cover the first etch stop layer SL1 on the active pixel region APR and the peripheral region PDR. On the active pixel region APR, each of the first patterns 155 may extend through the first material layer 153 in the vertical direction (Z direction). The first patterns 155 may be spaced apart from each other in the first horizontal direction (X direction). In an implementation, the first material layer 153 and the first patterns 155 may include a silicon oxide, a titanium oxide, a hafnium oxide, or the like. In an implementation, the first material layer 153 may include a silicon oxide, and each of the first patterns 155 may include a hafnium oxide.

A second etch stop layer SL2 may be between the first resonance layer 151 and the second resonance layer 152. The second etch stop layer SL2 may be flat on the first resonance layer 151 in the first horizontal direction (X direction). In an implementation, the second etch stop layer SL2 may be at the same vertical level on the active pixel region APR and on the peripheral region PDR. The second etch stop layer SL2 may include, e.g., a silicon oxide, a titanium oxide, or a hafnium oxide.

The second resonance layer 152 may be flat on the second etch stop layer SL2 in the first horizontal direction (X direction). In an implementation, the second resonance layer 152 may have the same thickness in the vertical direction (Z direction) on the active pixel region APR and on the peripheral region PDR. In an implementation, each of an upper surface and a lower surface of the second resonance layer 152 may be at the same vertical level on the active pixel region APR and on the peripheral region PDR.

The second resonance layer 152 may include a second material layer 154 and a plurality of second patterns 156. The second material layer 154 may cover the second etch stop layer SL2 on the active pixel region APR and on the peripheral region PDR. On the active pixel region APR, each of the second patterns 156 may extend through the second material layer 154 in the vertical direction (Z direction). The second patterns 156 may be spaced apart from each other in the first horizontal direction (X direction). In an implementation, as illustrated in FIGS. 3 and 4, a width of each of the first patterns 155 in the first horizontal direction (X direction) may be less than the width of each of the second patterns 156 in the first horizontal direction (X direction). In an implementation, the width of the first patterns 155 in the first horizontal direction (X direction) and the width of the second patterns 156 1 in the first horizontal direction (X direction) may vary according to the wavelength of light resonating in the resonance layer 150, and as a result, the ratio of materials included in the resonance layer 150 may be adjusted depending on the wavelength of light resonating in the resonance layer 150. In an implementation, the second material layer 154 may include a material that is substantially the same as or similar to a material included in the first material layer 153. In an implementation, the second patterns 156 may include a material that is substantially the same as or similar to a material included in the first patterns 155. In an implementation, the first material layer 153 and the second material layer 154 may include a silicon oxide, and each of the first patterns 155 and the second patterns 156 may include a hafnium oxide.

The upper reflective layer 160 may be on the resonance layer 150. The upper reflective layer 160 may be flat on the resonance layer 150 in the first horizontal direction (X direction). In an implementation, the upper reflective layer 160 may be at the same vertical level on the active pixel region APR and on the peripheral region PDR. The upper reflective layer 160 may include a first upper reflective layer 161, a second upper reflective layer 163, a third upper reflective layer 165, and a fourth upper reflective layer 167 that are sequentially stacked on the resonance layer 150. In an implementation, each of the first to fourth upper reflective layers 161, 163, 165, and 167 may include an insulating material such as a silicon oxide or a titanium oxide. In an implementation, the first upper reflective layer 161 and the third upper reflective layer 165 may include the same material. In an implementation, the first upper reflective layer 161 and the third upper reflective layer 165 may include a titanium oxide. In an implementation, the second upper reflective layer 163 and the fourth upper reflective layer 167 may include the same material. In an implementation, the second upper reflective layer 163 and the fourth upper reflective layer 167 may include a silicon oxide. In an implementation, the first upper reflective layer 161 and the third upper reflective layer 165 may include the same material, the second upper reflective layer 163 and the fourth upper reflective layer 167 may include the same material, and the material included in the first upper reflective layer 161 and the third upper reflective layer 165 may be different from the material included in the second upper reflective layer 163 and the fourth upper reflective layer 167. In an implementation, the first upper reflective layer 161 and the third upper reflective layer 165 may include a titanium oxide, and the second upper reflective layer 163 and the fourth upper reflective layer 167 may include a silicon oxide. In an implementation, as illustrated in FIGS. 3 and 4, the upper reflective layer 160 may have a stacked structure in which four layers are stacked in the vertical direction (Z direction), or a different number of layers may be included.

The first color filters CF1 may be on the upper reflective layer 160 on the active pixel region APR, and the second color filter CF2 may be on the upper reflective layer 160 on the peripheral region PDR.

The first color filters CF1 may be on the pixels PX, respectively. The first color filters CF1 may include primary color filters. The first color filters CF1 may include a plurality of color filters having different colors. In an implementation, each of the color filters may include green, red, and blue filters. The color filters may be arranged in a Bayer pattern. In an implementation, the color filters may have other colors such as cyan, magenta, or yellow.

The second color filter CF2 may include a primary color filter. In an implementation, the second color filter CF2 may include a blue filter.

The micro-lens ML may be on the first color filters CF1. The micro-lens ML may overlap the pixels PX in the vertical direction (Z direction). The micro-lens ML may have a convex shape to condense light incident from the outside. The micro-lens ML may include an organic material. The organic material may include, e.g., a photoresist material or a thermosetting resin.

In an implementation, the image sensor 100 may include the lower reflective layer 140, the resonance layer 150, and the upper reflective layer 160 that are sequentially on the substrate 110 including the active pixel region APR and the peripheral region PDR, and the thickness of the resonance layer 150 in the vertical direction (Z direction) may be greater on the active pixel region APR than on the peripheral region PDR. In an implementation, a height difference that could occur between the active pixel region ADR and the peripheral region PDR due to the metal layer 130 may be controlled.

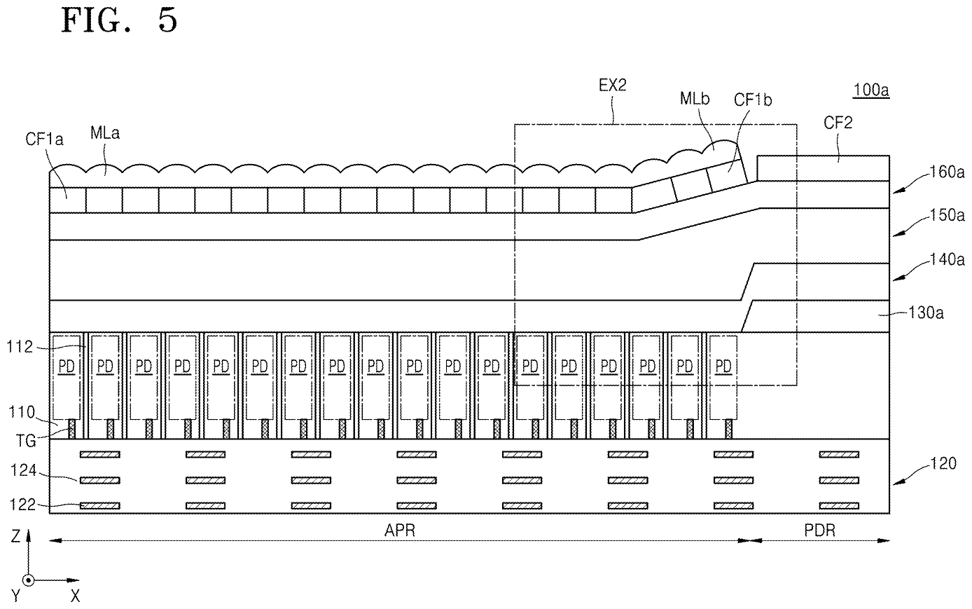

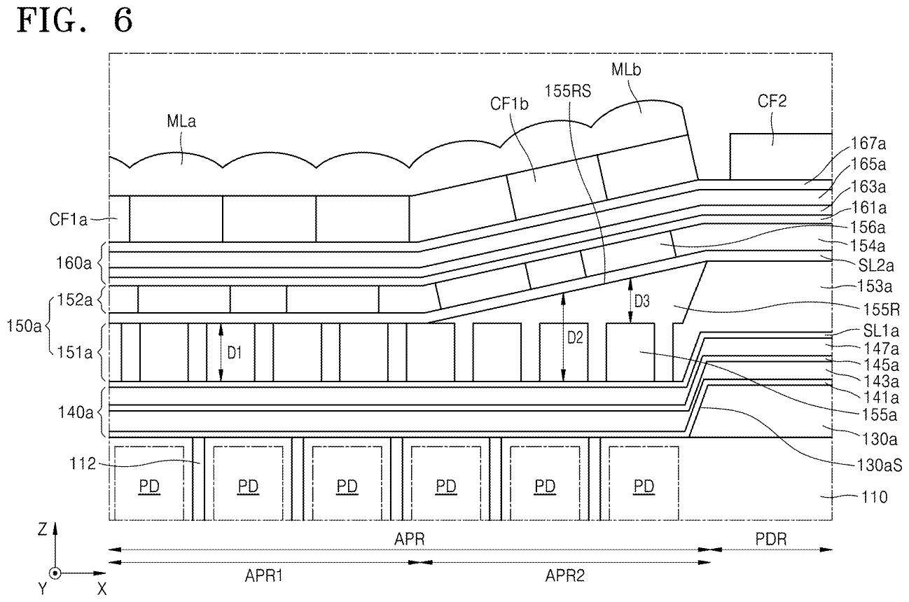

FIG. 5 is a cross-sectional view illustrating an image sensor 100a according to an embodiment. FIG. 6 is an enlarged cross-sectional view illustrating a portion EX2 of FIG. 5. Components of the image sensor 100a shown in FIGS. 5 and 6 are similar to the components of the image sensor 100 described with reference to FIGS. 2 to 4, and thus, differences thereof are mainly described.

Referring to FIGS. 5 and 6, the image sensor 100a may include a substrate 110, a wiring structure 120, a metal layer 130a, a lower reflective layer 140a, a resonance layer 150a, an upper reflective layer 160a, first and second color filters CF1a, CF2b, and CF2, and micro-lenses MLa and MLb.

The substrate 110 may include an active pixel region APR and a peripheral region PDR. The active pixel region APR may include a plurality of pixels PX. A plurality of photoelectric conversion regions PD may be in the pixels PX, respectively. In an implementation, the active pixel region APR may include an active region APR1 and a dummy region APR2. In an implementation, the active region APR1 may be a region on which the wiring structure 120 performs signal processing on electrical signals generated by the photoelectric conversion regions PD, and the dummy region APR2 may be a region on which the wiring structure 120 does not perform signal processing on the electrical signals generated by the photoelectric conversion regions PD. The peripheral region PDR may surround the active pixel region APR. In an implementation, the peripheral region PDR may be a region including pad terminals. In an implementation, the peripheral region PDR may be a region including optical black pixels.

The photoelectric conversion regions PD and transfer gates TG may be in or on the active pixel region ARP of the substrate 110. A pixel isolation structure 112 may extend through the substrate 110 in the vertical direction (Z direction) perpendicular to an upper surface of the substrate 110. The wiring structure 120 may be on a lower surface (e.g., a front surface) of the substrate 110. The wiring structure 120 may include a plurality of wiring layers 122 and an insulating layer 124. In an implementation, a support substrate may be on a lower surface of the wiring structure 120.

The substrate 110, the wiring structure 120, the photoelectric conversion regions PD, and the transfer gates TG of the image sensor 100a may be substantially the same as or similar to the substrate 110, the wiring structure 120, the photoelectric conversion regions PD, and the transfer gates TG of the image sensor 100 that are described with reference to FIGS. 2 to 4.

The metal layer 130a may be on the upper surface of the substrate 110 on the peripheral region PDR. The lower reflective layer 140a may be on the substrate 110. The lower reflective layer 140a may cover the upper surface of the substrate 110 on the active pixel region APR and may cover the metal layer 130a on the peripheral region PDR. A first etch stop layer SL1a may be on the lower reflective layer 140a.

The metal layer 130a, the lower reflective layer 140a, and the first etch stop layer SL1a may be substantially the same as or similar to the metal layer 130, the lower reflective layer 140, and the first etch stop layer SL1 described with reference to FIGS. 2 to 4, respectively.

The resonance layer 150a may be on the first etch stop layer SL1a. The resonance layer 150a may include a first resonance layer 151a on the first etch stop layer SL1a, and a second resonance layer 152a on the first resonance layer 151a.

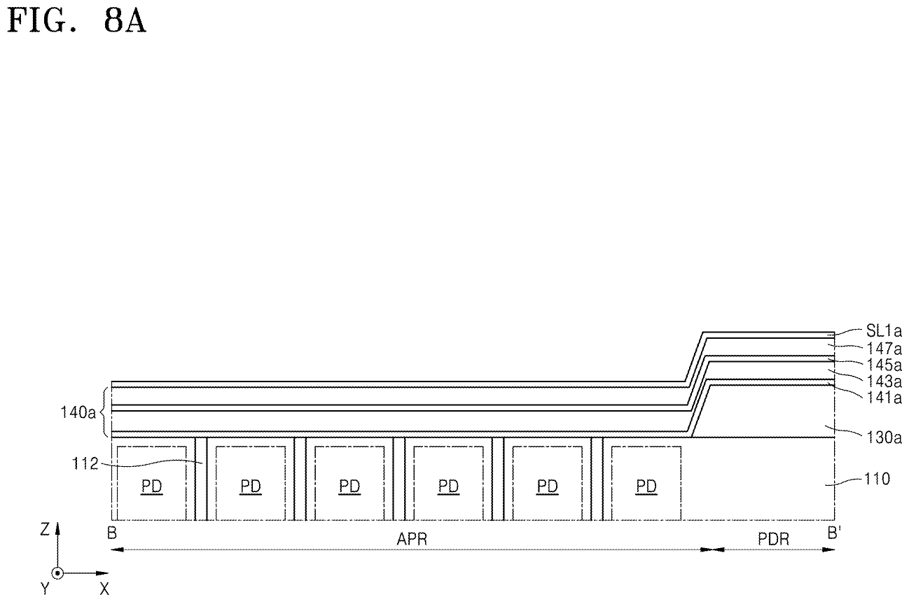

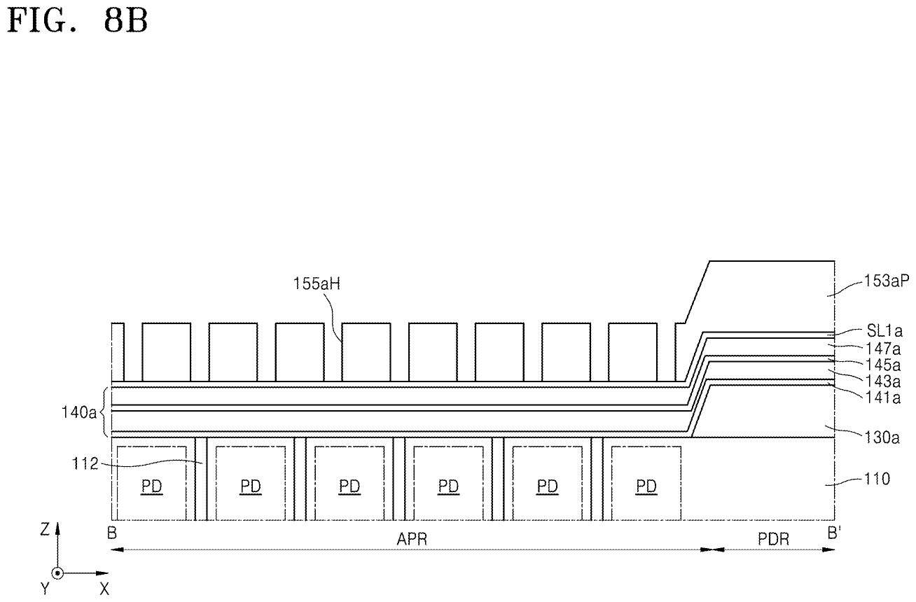

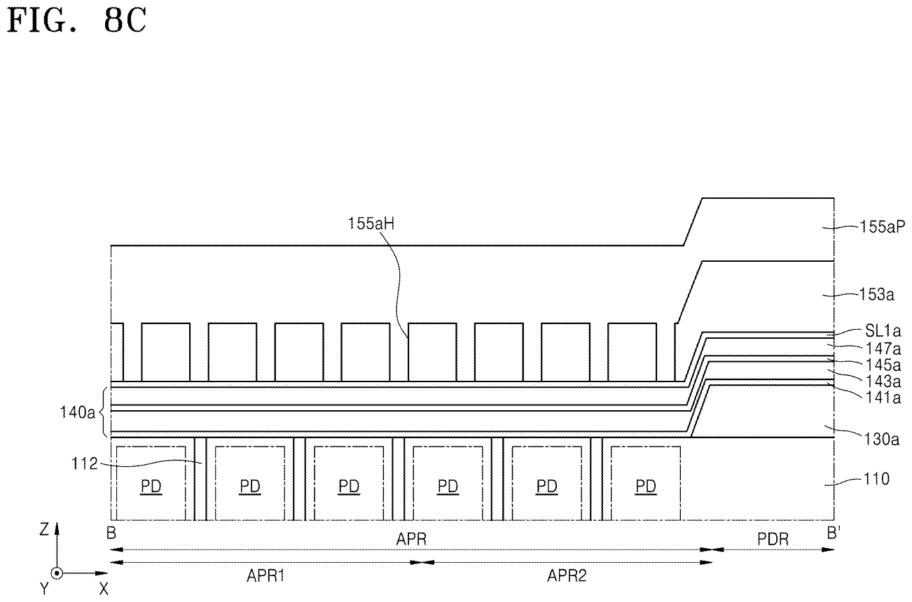

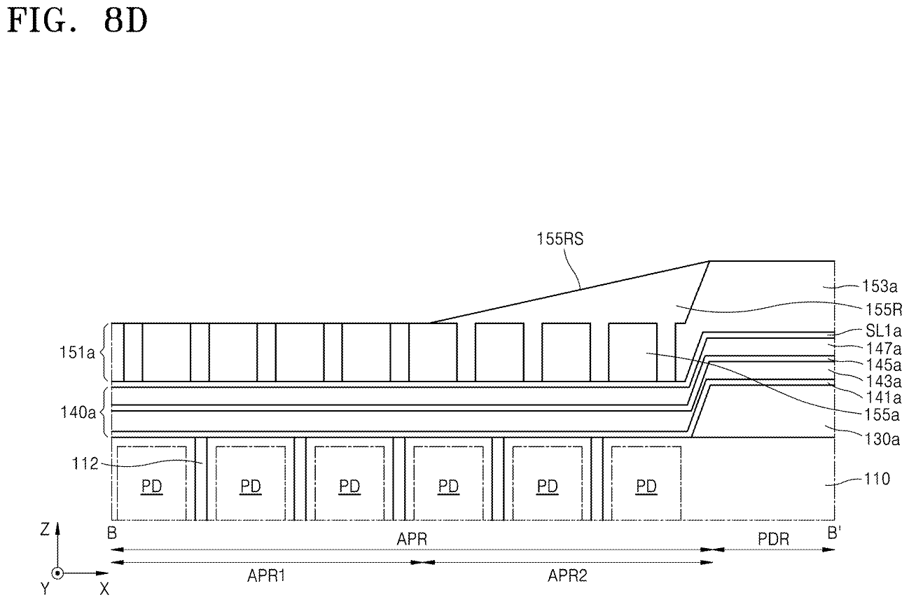

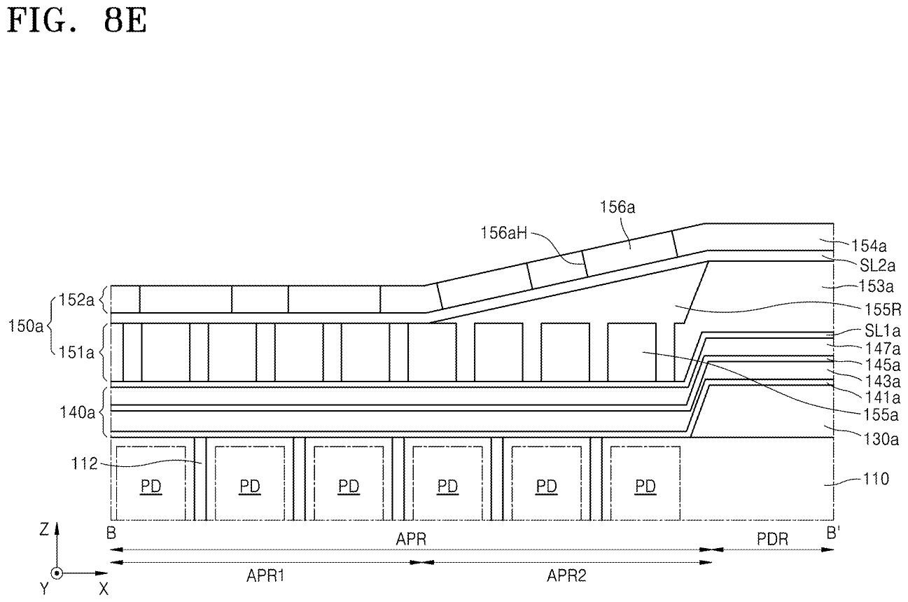

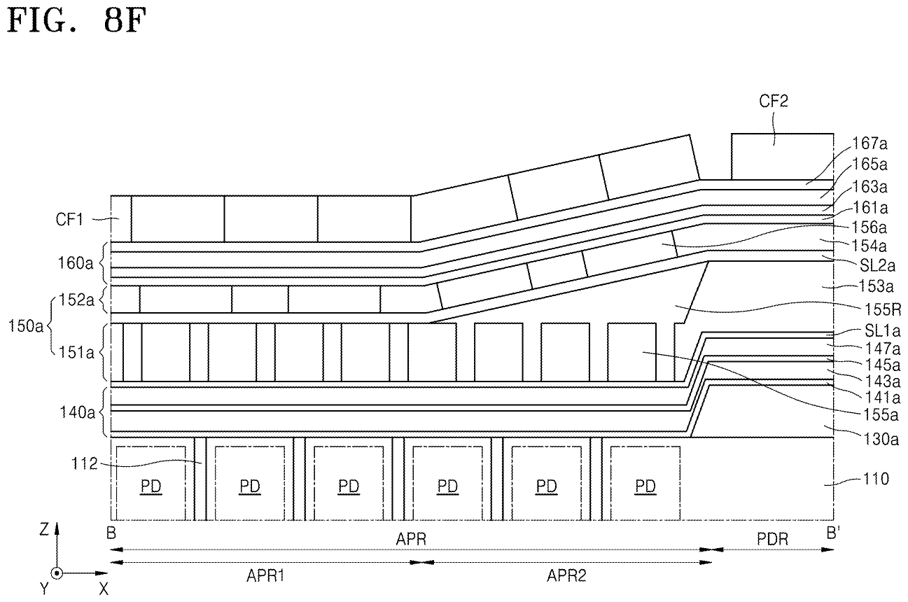

The first resonance layer 151a may include a first material layer 153a, a plurality of first patterns 155a, and a first residual layer 155R. The first material layer 153a may cover the first etch stop layer SL1a on the active pixel region APR and on the peripheral region PDR. On the active pixel region APR, each of the first patterns 155a may extend through the first material layer 153a in the vertical direction (Z direction). The first residual layer 155R may be on the first material layer 153a and the first patterns 155a on the dummy region APR2. The first residual layer 155R may have an upper surface 155RS that is inclined downwardly from the peripheral region PDR toward the active pixel region APR. In an implementation, the first residual layer 155R may have a thickness D3 in the vertical direction (Z direction) that gradually increases in a direction toward the peripheral region PDR. In an implementation, the first residual layer 155R may have the inclined upper surface 155RS, the first resonance layer 151a including the first residual layer 155R may have a first thickness D1 in the vertical direction (Z direction) on the active region APR1 and a second thickness D2 in the vertical direction (Z direction) on the dummy region APR2, and the second thickness D2 may be greater than the first thickness D1. In an implementation, the first material layer 153a, the first patterns 155a, and the first residual layer 155R may include a silicon oxide, a titanium oxide, a hafnium oxide, or the like. In an implementation, the first material layer 153a may include a silicon oxide, and each of the first patterns 155a and the first residual layer 155R may include a hafnium oxide. As described below with reference to FIGS. 8A to 8F, the first residual layer 155R and each of the first patterns 155a may be formed in one piece. In an implementation, the first residual layer 155R and each of the first patterns 155a may include the same material. In an implementation, the first residual layer 155R and each of the first patterns 155a may include a hafnium oxide.

A second etch stop layer SL2a may be between the first resonance layer 151a and the second resonance layer 152a. A portion of the second etch stop layer SL2a overlapping the dummy region APR2 may be inclined along the upper surface 155RS of the first residual layer 155R, and the rest of the second etch stop layer SL2a other than the overlapping portion may be flat in a first horizontal direction (X direction). In an implementation, the vertical level of the second etch stop layer SL2a may be higher on the peripheral region PDR than on the active pixel region APR. The second etch stop layer SL2a may include, e.g., a silicon oxide, a titanium oxide, or a hafnium oxide.

A portion of the second resonance layer 152a overlapping the dummy region APR2 may have the same slope as the slope of the upper surface 155RS of the first residual layer 155R, and the rest of the second resonance layer 152a other than the overlapping portion may be flat in the first horizontal direction (X direction). In an implementation, the vertical level of the second resonance layer 152a may be higher on the peripheral region PDR than on the active pixel region APR.

The second resonance layer 152a may include a second material layer 154a and a plurality of second patterns 156a. The second material layer 154a may cover the second etch stop layer SL2a on the active pixel region APR and on the peripheral region PDR. On the active pixel region APR, each of the second patterns 156a may extend through the second material layer 154a in the vertical direction (Z direction). The second patterns 156a may be apart from each other in the first horizontal direction (X direction). Some of the second patterns 156a overlapping the dummy region APR2 may be on the second etch stop layer SL2a and may have the same slope as the slope of the upper surface 155RS of the first residual layer 155R. In an implementation, the second material layer 154a may include a material that is substantially the same as or similar to a material included in the first material layer 153a. In an implementation, the second patterns 156a may include a material that is substantially the same as or similar to a material included in the first patterns 155a.

The upper reflective layer 160a may be on the resonance layer 150a. A portion of the upper reflective layer 160a overlapping the dummy region APR2 may be on the second resonance layer 152a and may have the same slope as the slope of the upper surface 155RS of the first residual layer 155R, and the rest of the upper reflective layer 160a other than the overlapping portion may be flat in the first horizontal direction (X direction). In an implementation, the vertical level of the upper reflective layer 160a may be higher on the peripheral region PDR than on the active pixel region APR. The upper reflective layer 160a may include a first upper reflective layer 161a, a second upper reflective layer 163a, a third upper reflective layer 165a, and a fourth upper reflective layer 167a that are sequentially stacked on the resonance layer 150a. In an implementation, each of the first to fourth upper reflective layers 161a, 163a, 165a, and 167a may include an insulating material such as a silicon oxide or a titanium oxide. In an implementation, the first upper reflective layer 161a and the third upper reflective layer 165a may include the same material. In an implementation, the second upper reflective layer 163a and the fourth upper reflective layer 167a may include the same material. In an implementation, the first upper reflective layer 161a and the third upper reflective layer 165a may include the same material, the second upper reflective layer 163a and the fourth upper reflective layer 167a may include the same material, and the material included in the first upper reflective layer 161a and the third upper reflective layer 165a may be different from the material included in the second upper reflective layer 163a and the fourth upper reflective layer 167a.

The first color filters CF1a and CF1b may be on the upper reflective layer 160a on the active pixel region APR, and the second color filter CF2 may be on the upper reflective layer 160a on the peripheral region PDR.

The first color filters CF1a and CF1b may include an active region color filters CF1a and dummy region color filters CF1b. The active region color filters CF1a may be on the upper reflective layer 160a on the active region APR1, and the dummy region color filters CF1b may be on the upper reflective layer 160a on the dummy region APR2. In an implementation, the active region color filters CF1a may be on the upper reflective layer 160a in the first horizontal direction (X direction), and the dummy region color filter CF1b may be on the upper reflective layer 160a and may have the same slope as the slope of the upper surface 155RS of the first residual layer 155R.

In an implementation, the vertical level of the second color filter CF2 may be higher than the vertical levels of the first color filters CF1a and CF1b.

The micro-lenses MLa and MLb may be on the first color filters CF1a and CF1b. The micro-lenses MLa and MLb may include an active region micro-lens MLa and a dummy region micro-lens MLb. The active region micro-lens MLa may be on the active region color filters CF1a, and the dummy region micro-lens MLb may be on the dummy region color filters CF1b. In an implementation, the active region micro-lens MLa may be on the active region color filters CF1a in the first horizontal direction (X direction), and the dummy region micro-lens MLb may be on the dummy region color filters CF1b and may have the same slope as the slope of the upper surface 155RS of the first residual layer 155R.

FIGS. 7A to 7H are cross-sectional views of stages in a method of manufacturing an image sensor 100, according to embodiments. FIGS. 7A to 7H are enlarged cross-sectional views illustrating a portion corresponding to the portion EX1 of FIG. 3.

Referring to FIG. 7A, a substrate 110 having a wiring structure 120 (refer to FIG. 3) on a lower surface of the substrate 110 may be provided, and a metal layer 130, a lower reflective layer 140, and a first etch stop layer SL1 may be sequentially formed on an upper surface of the substrate 110. The metal layer 130, the lower reflective layer 140, and the first etch stop layer SL1 may be formed through, e.g., a deposition process. The metal layer 130 may have a sidewall 130S that is inclined downwardly from a peripheral region PDR toward an active pixel region APR, and a portion of the lower reflective layer 140 overlapping the sidewall 130S in a vertical direction (Z direction), and a portion of the first etch stop layer SL1 overlapping the sidewall 130S in the vertical direction (Z direction) may have the same slope as the slope of the sidewall 130S.

Referring to FIG. 7B, a material layer 153P may be formed on a resultant structure shown in FIG. 7A to cover the first etch stop layer SL1. The material layer 153P may be formed through, e.g., a deposition process. The material layer 153P may include, e.g., a silicon oxide. The portion of the first etch stop layer SL1 overlapping the sidewall 130S in the vertical direction (Z direction) may have the same slope as the slope of the sidewall 130S, and a portion of the material layer 153P overlapping the sidewall 130S in the vertical direction (Z direction) may also have the same slope as the slope of the sidewall 130S.

Referring to FIG. 7C, in a result structure shown in FIG. 7B, the material layer 153P may be etched on the peripheral region PDR. Owing to the etching, a first through-hole 153H extending through a portion of the material layer 153P may be formed in the vertical direction (Z direction). A residual material layer 153PR that is not removed by the etching may be adjacent to the first through-hole 153H.

Referring to FIG. 7D, in a resultant structure shown in FIG. 7C, the material layer 153P may be planarized. The planarizing may be performed through, e.g., a chemical mechanical polishing (CMP) process. Owing to the planarizing, the residual material layer 153PR may be removed, and an upper surface of the material layer 153P may be flattened in a first horizontal direction (X direction).

Referring to FIG. 7E, in a resultant structure shown in FIG. 7D, the material layer 153P may be etched in the active pixel region APR. Through the etching, a plurality of pattern holes 155H extending through the material layer 153P in the vertical direction (Z direction) may be formed. The first etch stop layer SL1 may be exposed through bottom surfaces of the pattern holes 155H. The pattern holes 155H may be formed to be spaced apart from each other in the material layer 153P.

Referring to FIG. 7F, in a resultant structure shown in FIG. 7E, a second material layer may be formed to fill the pattern holes 155H (refer to FIG. 7E) and cover an upper surface of the material layer 153P (refer to FIG. 7E), and the second material layer may be planarized. The second material layer may include, e.g., a titanium oxide. A first resonance layer 151 including a first material layer 153 and a plurality of first patterns 155 may be formed by planarizing the second material layer. During the etching described with reference to FIG. 7C and the planarizing described with reference to FIG. 7D, the material layer 153P may be removed from on the peripheral region PDR and may not be removed from on the active pixel region APR. In an implementation, the thickness of the first resonance layer 151 in the vertical direction (Z direction) may be greater on the active pixel region APR than on the peripheral region PDR. In an implementation, during the etching described with reference to FIG. 7C and the planarizing described with reference to FIG. 7D, an upper surface of the first resonance layer 151 may be adjusted to be at the same vertical level on the peripheral region PDR and on the active pixel region APR.

Referring to FIG. 7G, in a resultant structure shown in FIG. 7F, a second etch stop layer SL2 and a second resonance layer 152 may be sequentially formed on the first resonance layer 151. Like the first resonance layer 151, the second resonance layer 152 may be formed by forming a material layer on the second etch stop layer SL2, etching the material layer to form through-holes, forming a material layer to fill the through-holes, and planarizing the material layer filling the through-holes.

Referring to FIG. 7H, in a resultant structure shown in FIG. 7G, an upper reflective layer 160 may be formed on the second resonance layer 152, first color filters CF1 may be formed on the upper reflective layer 160 in the active pixel region APR, and a second color filter CF2 may be formed on the upper reflective layer 160 in the peripheral region PDR.

Next, in a resultant structure shown in FIG. 7H, a micro-lens ML may be formed on the first color filters CF1, thereby manufacturing the image sensor 100 described with reference to FIGS. 2 to 4.

FIGS. 8A to 8F are cross-sectional views of stages in a method of manufacturing an image sensor 100a, according to embodiments. FIG. 8A to 8F are enlarged cross-sectional views of a portion corresponding to the portion EX2 of FIG. 5.

Referring to FIG. 8A, a substrate 110 having a wiring structure 120 (refer to FIG. 3) on a lower surface of the substrate 110 may be provided, and a metal layer 130a, a lower reflective layer 140a, and a first etch stop layer SL1a may be sequentially formed on an upper surface of the substrate 110. The metal layer 130a may have a sidewall 130aS inclined downwardly from a peripheral region PDR toward an active pixel region APR, and a portion of the lower reflective layer 140a overlapping the sidewall 130aS in a vertical direction (Z direction), and a portion of the first etch stop layer SL1a overlapping the sidewall 130aS in the vertical direction (Z direction) may have the same slope as the slope of the sidewall 130aS.

Referring to FIG. 8B, in a resultant structure shown in FIG. 8A, a material layer 153aP covering the first etch stop layer SL1a may be formed. The material layer 153aP may include, e.g., a silicon oxide. The portion of the first etch stop layer SL1a overlapping the sidewall 130aS in the vertical direction (Z direction) may have the same slope as the slope of the sidewall 130aS, and a portion of the material layer 153aP overlapping the sidewall 130aS in the vertical direction (Z direction) may also have the same slope as the slope of the sidewall 130aS. Next, the material layer 153aP may be etched in the active pixel region APR. Owing to the etching, a plurality of pattern holes 155aH extending through the material layer 153aP in the vertical direction (Z direction) may be formed. The first etch stop layer SL1a may be exposed through bottom surfaces of the pattern holes 155aH. The pattern holes 155aH may be formed to be spaced apart from each other in the material layer 153aP.

Referring to FIG. 8C, in a resultant structure shown in FIG. 8B, a material layer 155aP may be formed to fill the pattern holes 155aH and cover an upper surface of the material layer 153aP. In an implementation, a portion of the material layer 155aP overlapping the sidewall 130aS in the vertical direction (Z direction) may have the same slope as the slope of the sidewall 130aS.

Referring to FIG. 8D, in a resultant structure shown in FIG. 8C, the material layer 155aP may be planarized. In an implementation, the portion of the material layer 155aP overlapping the sidewall 130aS in the vertical direction (Z direction) may be inclined, and the portion of the material layer 155aP may not be completely removed by the planarizing and may partially remain. In an implementation, a first residual layer 155R may be formed by the non-removed portion of the material layer 155aP. In an implementation, a region of the active pixel region APR on which the first residual layer 155R is not formed may be referred to as an active region APR1, and a region of the active pixel region APR on which the first residual layer 155R is formed may be referred to as a dummy region APR2. The first residual layer 155R may have an upper surface that is inclined downwardly from the peripheral region PDR toward the active pixel region APR. Owing to the planarizing, a first resonance layer 151a including a first material layer 153a, first patterns 155a, and the first residual layer 155R may be formed.

Referring to FIG. 8E, in a resultant structure shown in FIG. 8D, a second etch stop layer SL2a and a second resonance layer 152a may be sequentially formed on the first resonance layer 151a. Like the first resonance layer 151a, the second resonance layer 152a may be formed by forming a material layer, etching the material layer to form pattern holes, forming a material layer to fill the pattern holes, and planarizing the material layer. On the dummy region APR2, the second etch stop layer SL2a and the second resonance layer 152a may have the same slope as the slope of an upper surface 155RS of the first residual layer 155R.

Referring to FIG. 8F, in a resultant structure shown in FIG. 8E, an upper reflective layer 160a may be formed on the second resonance layer 152a. Next, active region color filters CF1a may be formed on the upper reflective layer 160a on the active region APR1, dummy region color filters CF1b may be formed on the upper reflective layer 160a on the dummy region APR2, and a second color filter CF2 may be formed on the upper reflective layer 160a on the peripheral region PDR. In an implementation, the upper reflective layer 160a may have the same slope as the slope of the upper surface 155RS of the first residual layer 155R on the dummy region APR2, and the dummy region color filters CF1b may also have the same slope as the slope of the upper surface 155RS of the first residual layer 155R.

Next, in a resultant structure shown in FIG. 8F, an active region micro-lens MLa may be formed on the active region color filters CF1a, and a dummy region micro-lens MLb may be formed on the dummy region color filters CF1b, thereby manufacturing the image sensor 100a described with reference to FIGS. 5 and 6.

By way of summation and review, the degree of integration of image sensors has increased, and thus, the size of pixels and the size of components of pixel circuits have also decreased.

One or more embodiments may provide an image sensor including a resonance layer.

One or more embodiments may provide an image sensor configured to address a height difference between an active pixel region and a peripheral region.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor, comprising:
a substrate including an active pixel region and a peripheral region surrounding the active pixel region;
a metal layer on the peripheral region of the substrate;
a lower reflective layer on the substrate and the metal layer;
a resonance layer on the lower reflective layer; and
an upper reflective layer on the resonance layer,
wherein:
the resonance layer has a first thickness on the active pixel region in a vertical direction perpendicular to an upper surface of the substrate and a second thickness in the vertical direction on the peripheral region, and
the first thickness is greater than the second thickness.

2. The image sensor as claimed in claim 1, wherein:
a vertical level of an upper surface of the resonance layer on the active pixel region is the same as a vertical level of the upper surface of the resonance layer on the peripheral region, and
a vertical level of a lower surface of the resonance layer on the peripheral region is higher than a vertical level of the lower surface of the resonance layer on the active pixel region.

3. The image sensor as claimed in claim 1, wherein:
the resonance layer includes a first resonance layer on the lower reflective layer and a second resonance layer on the first resonance layer,
the first resonance layer has a first thickness in the vertical direction on the active pixel region and a second thickness in the vertical direction on the peripheral region, and
a thickness in the vertical direction of the second resonance layer on the active pixel region is the same as a thickness in the vertical direction of the second resonance layer on the peripheral region.

4. The image sensor as claimed in claim 3, wherein:
a vertical level of an upper surface of the first resonance layer on the active pixel region is the same as a vertical level of the upper surface of the first resonance layer on the peripheral region, and
a vertical level of a lower surface of the first resonance layer on the peripheral region is higher than a vertical level of the lower surface of the first resonance layer on the active pixel region.

5. The image sensor as claimed in claim 3, wherein:
a vertical level of an upper surface of the second resonance layer on the active pixel region is the same as a vertical level of the upper surface of the second resonance layer on the peripheral region, and
a vertical level of a lower surface of the second resonance layer on the active pixel region is the same as a vertical level of the lower surface of the second resonance layer on the peripheral region.

6. The image sensor as claimed in claim 1, wherein a vertical level of the upper reflective layer on the active pixel region is the same as a vertical level of the upper reflective layer on the peripheral region.

7. The image sensor as claimed in claim 1, further comprising:
a first etch stop layer between the resonance layer and the lower reflective layer; and
a second etch stop layer between the resonance layer and the upper reflective layer,
wherein:
a vertical level of the first etch stop layer on the peripheral region is higher than a vertical level of the first etch stop layer on the active pixel region, and
a vertical level of the second etch stop layer on the active pixel region is the same as a vertical level of the second etch stop layer on the peripheral region.

8. The image sensor as claimed in claim 1, wherein the resonance layer includes:
a first material layer covering the lower reflective layer on the active pixel region and on the peripheral region; and
first patterns extending in the vertical direction through the first material layer on the active pixel region.

9. An image sensor, comprising:
a substrate including an active pixel region and a peripheral region surrounding the active pixel region, the active pixel region including an active region and a dummy region;
a wiring structure on a lower surface of the substrate;
a metal layer on the peripheral region of the substrate;
a lower reflective layer on the substrate and the metal layer;
a resonance layer on the lower reflective layer; and
an upper reflective layer on the resonance layer,
wherein the resonance layer includes:
a first material layer covering the lower reflective layer on the active pixel region and on the peripheral region,
first patterns extending through the first material layer on the active pixel region in a vertical direction perpendicular to an upper surface of the substrate, and
a first residual layer on the first material layer and the first patterns on the dummy region.

10. The image sensor as claimed in claim 9, wherein the first residual layer has an upper surface that is inclined downwardly from the peripheral region toward the active pixel region.

11. The image sensor as claimed in claim 9, wherein the first residual layer has a thickness in the vertical direction that increases in a direction toward the peripheral region.

12. The image sensor as claimed in claim 9, wherein the first patterns and the first residual layer include a same material.

13. The image sensor as claimed in claim 9, wherein:
the resonance layer has a first thickness in the vertical direction on the active region and a second thickness in the vertical direction on the dummy region, and
the second thickness is greater than the first thickness.

14. The image sensor as claimed in claim 9, wherein, on the dummy region, the upper reflective layer has a slope equal to a slope of an upper surface of the first residual layer.

15. The image sensor as claimed in claim 9, further comprising a plurality of color filters on the upper reflective layer, wherein some color filters of the plurality of color filters on the dummy region have a slope equal to a slope of an upper surface of the first residual layer.

16. The image sensor as claimed in claim 15, wherein:
the plurality of color filters includes a first color filter on the active pixel region and a second color filter on the peripheral region, and
the second color filter is at a higher vertical level than a vertical level of the first color filter.

17. The image sensor as claimed in claim 9, wherein:
the substrate includes photoelectric conversion regions on the active region and the dummy region,
electrical signals generated in the photoelectric conversion regions on the active region are processed in the wiring structure, and
electrical signals generated in the photoelectric conversion regions on the dummy region are not processed in the wiring structure.

18. An image sensor, comprising:
a substrate including an active pixel region and a peripheral region surrounding the active pixel region;
a metal layer on the peripheral region of the substrate;
a lower reflective layer on the substrate and the metal layer;
a resonance layer including a first resonance layer and a second resonance layer that are sequentially on the lower reflective layer;
an upper reflective layer on the resonance layer;
a plurality of color filters including a first color filter on the upper reflective layer on the active pixel region and a second color filter on the upper reflective layer on the peripheral region; and
a micro-lens on the first color filter,
wherein:
the first resonance layer has a first thickness in a vertical direction perpendicular to an upper surface of the substrate on the active pixel region and a second thickness in the vertical direction on the peripheral region,
the first thickness is greater than the second thickness, and
a thickness in the vertical direction of the second resonance layer on the active pixel region is the same as a thickness in the vertical direction of the second resonance layer on the peripheral region.

19. The image sensor as claimed in claim 18, wherein:
a vertical level of an upper surface of the first resonance layer on the active pixel region is the same as a vertical level of the upper surface of the first resonance layer on the peripheral region,
a vertical level of a lower surface of the first resonance layer on the peripheral region is higher than a vertical level of the lower surface of the first resonance layer on the active pixel region,
a vertical level of an upper surface of the second resonance layer on the active pixel region is the same as a vertical level of the upper surface of the second resonance layer on the peripheral region, and
a vertical level of a lower surface of the second resonance layer on the active pixel region is the same as a vertical level of the lower surface of the second resonance layer on the peripheral region.

20. The image sensor as claimed in claim 18, wherein the upper reflective layer is at a same vertical level on the active pixel region and on the peripheral region.
